(19) United States
(12) Patent Application Publication
(10) Pub. No.: US 2023/0222025 A1
(43) Pub. Date: Jul. 13, 2023

(54) RAS (RELIABILITY, AVAILABILITY, AND SERVICEABILITY)-BASED MEMORY DOMAINS

(71) Applicant: Intel Corporation, Santa Clara, CA (US)

(72) Inventors: Karthik KUMAR, Chandler, AZ (US); Francesc GUIM BERNAT, Barcelona (ES); Mark A. SCHMISSEUR, Phoenix, AZ (US); Thomas WILLHALM, Sandhausen (DE); Marcos E. CARRANZA, Portland, OR (US)

(21) Appl. No.: 18/124,453

(22) Filed: Mar. 21, 2023

(51) Int. Cl. G06F 11/00; G06F 11/14

(52) U.S. Cl. CPC G06F 11/008; G06F 11/142

(57) ABSTRACT

Reliability, availability, and serviceability (RAS)-based memory domains can enable applications to store data in memory domains having different degrees of reliability to reduce downtime and data corruption due to memory errors. In one example, memory resources are classified into different RAS-based memory domains based on their expected likelihood of encountering errors. The mapping of memory resources into RAS-based memory domains can be dynamically managed and updated when information indicative of reliability (such as the occurrence of errors or other information) suggests that a memory resource is becoming less reliable. The RAS-based memory domains can be exposed to applications to enable applications to allocate memory in high reliability memory for critical data.

### FIELD

Descriptions are generally related to computer memory, and more particular descriptions are related to RAS-based domains for memory.

### BACKGROUND

There are a variety of computer memory technologies with varying techniques for preventing and mitigating errors; however, memory errors continue to be a hindrance to achieving desired system performance and uptime. This is especially true for the owners and operators of large data centers and cloud service providers (e.g., hyperscalers), which perform large memory application deployments. With the rapid growth in data volumes and the need to access data at memory speeds (e.g., for real time analytics, artificial intelligence (AI), etc.), the demand for memory capacity continues to increase across multiple domains in the cloud. With the increasing demand for capacity usage, there has been heightened focus on memory reliability and application recoverability.

### BRIEF DESCRIPTION OF THE DRAWINGS

The following description includes discussion of figures having illustrations given by way of example of an implementation. The drawings should be understood by way of example, and not by way of limitation. As used herein, references to one or more examples are to be understood as describing a particular feature, structure, or characteristic included in at least one implementation of the invention. Phrases such as “in one example” or “in an alternative example” appearing herein provide examples of implementations of the invention, and do not necessarily all refer to the same implementation. However, they are also not necessarily mutually exclusive.

FIG. 1 illustrates a block diagram showing techniques for handling memory errors in hardware and software.

FIG. 2 illustrates spatial memory regions for a sample database application.

FIG. 3 is a block diagram of a system in which RAS-based memory domains can be implemented.

FIG. 4 is a block diagram of a system in which RAS-based memory domains can be implemented.

FIG. 5 is a block diagram of a system in which RAS-based memory domains can be implemented.

FIGS. 6-9 are flow diagrams of examples of methods for implementing RAS-based memory domains.

FIGS. 10A-10C illustrate an example of reclassification of a memory range from a high RAS memory domain to a lower RAS normal (lower) RAS memory domain.

FIG. 11 is a block diagram of an example of a memory subsystem in which a RAS-based memory domains can be implemented.

FIG. 12 illustrates an example computing system in which RAS-based memory domains can be implemented.

Descriptions of certain details and implementations follow, including non-limiting descriptions of the figures, which may depict some or all examples, and well as other potential implementations.

### DETAILED DESCRIPTION

As described herein, RAS-based memory domains can enable applications to store data in memory domains having different degrees of reliability to reduce downtime and data corruption due to memory errors. In one example, memory resources are classified into different RAS-based memory domains based on their expected likelihood of encountering errors. The mapping of memory resources into RAS-based memory domains can be dynamically managed and updated when information indicative of reliability (such as the occurrence of errors or other information) suggests that a memory resource is becoming less reliable. The RAS-based memory domains can be exposed to applications to enable applications to allocate memory in high reliability memory for critical data.

Memory errors have become a leading focus area for hyperscalers with large memory application deployments. For example, database as a service (DBaaS) deployments involving large amounts of memory per node can result in statistically higher memory error rates per node.

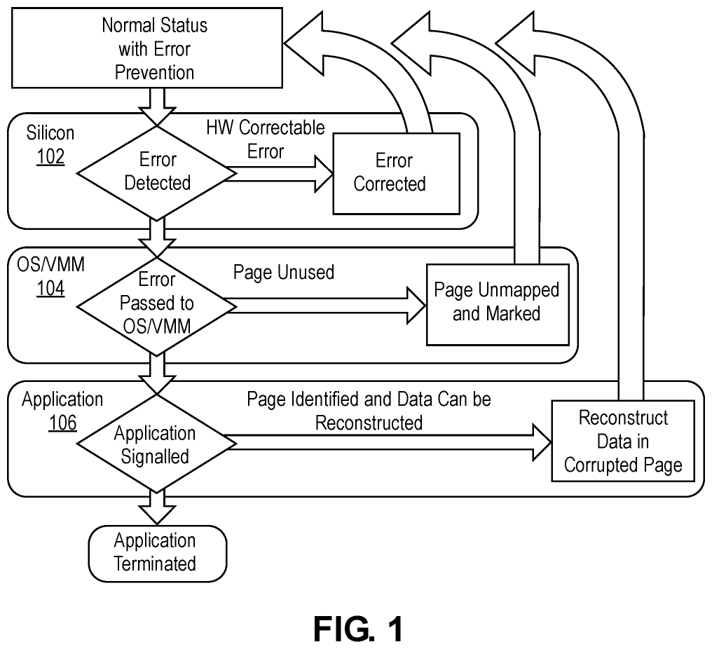

Some existing techniques attempt to reduce downtime due to memory errors; however, there have been some challenges with full application stack adoption. For example, FIG. 1 illustrates a block diagram showing techniques for handling memory errors in hardware and software. Some correctable errors can be handled in hardware (e.g., silicon 102) transparently. For example, some memory devices include error correction code (ECC) logic that can detect and correct at least some correctable errors. Secondly, if it is an uncorrectable error that occurs in a page that no one is using, the operating system or virtual machine manager (VMM) (e.g., OS/VMM 104) can handle the error by unmapping the page. For example, hardware can notify the OS/VMM 104 of an error, and the operating system or VMM can determine how to handle the error by unmapping the page and/or marking the page as bad.

In the case of uncorrectable errors in pages being used by applications, there is more complexity in handling the errors. In some cases, the data can be reconstructed; however, enterprise-class usage typically require full MCA-R (machine check recovery). Implementing a full MCA-R solution has been challenging due to the complexity of covering every single use case. For example, some regions of memory (e.g., database tables) are duplicated (e.g., in a disk) but others are no. Also, some regions of memory may be under a lock or be operated on by multiple threads, in which case an uncorrectable error typically needs all the threads accessing that line to be notified. In some cases, the data cannot be reconstructed by the application 106, and the application 106 is terminated. Thus, the techniques for handling uncorrectable errors in pages being used by applications can be especially complex and require adoption across the entire software stack.

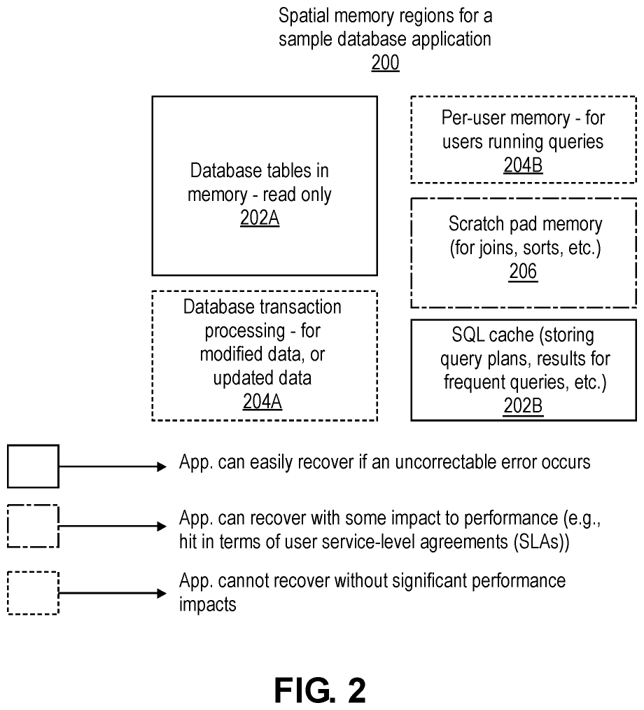

In addition to reactive techniques that handle memory errors after they occur, other solutions seek to predict memory failures. It is all but certain that we have memory errors, including uncorrectable ones. As different memory regions get used and accessed differently, over time, the probability of bit errors can increase. Memory failure prediction can be a function of usage, temperature, etc. As we get to more diverse landscapes, including memory pools, or greater numbers of DIMMs in a platform (e.g., tens of DIMMs or more), it becomes evident that all memory regions are not equal, and there existing techniques to identify where memory errors are more likely to occur. However, existing memory error prediction schemes fail to consider that not all data used by an application have the same tolerance for errors.

Where (from an application memory usage standpoint) uncorrectable memory errors occur matters in terms of the impact of the errors. Let us consider the following example, where there are different memory regions used by an application. For example, FIG. 2 illustrates spatial memory regions 200 for a sample database application. As can be seen in FIG. 2, encountering a memory error is not the same in all regions. In some memory regions 202A and 202B, the data can be easily reconstructed by the application and execution can proceed without any downtime for the end users. For example, the data may be reconstructed by loading the data from a disk, or the data may be recomputed (resulting in a performance hit) instead of using cached data. In other regions 204A and 204B, recovery is very difficult and there typically needs to be downtime and end user notification of the data error/corruption. For example, many applications are not thread safe and cannot handle exceptions to some transaction operations, or multi-thread updates. In other regions 206, the application can recover with some performance impact in terms of user SLAs. For example, the application can trace back which queries are impacted and rerun those queries. Thus, different memory regions used by an application's address space can have different recoverability from memory errors. Note that solid or dashed lines are used to denote memory regions having different impacts when errors are encountered A solid line is used to denote memory regions for which an application can easily recover if an uncorrectable error occurs, and different dashed lines are used to denote regions for which recovery is more difficult or in some cases not possible.

Given that not all memory regions are the same and that it is possible to know where memory errors are more likely to occur, techniques described herein enable data to be stored in different reliability memory domains. With at least two different reliability memory domains, error-sensitive data (e.g., data that cannot be recovered or that is recoverable but with significant performance impacts such as regions 204A and 204B of FIG. 2) can be stored in higher RAS-based memory domains, while less error-sensitive data (e.g., data that is more easily recoverable or recoverable with minimal performance impacts such as regions 202A and 202B of FIG. 2) can be stored in lower RAS-based memory domains. The term “RAS-based memory domain” is generally used throughout this disclosure; however, other terms such as “reliability domain,” “reliability memory domain,” “reliability memory region,” “RAS domain,” “RAS memory domain,” “RAS NUMA domain, and “RAS-based NUMA domain” can be used interchangeably. A RAS-based memory domain can be thought of as a RAS-based nonuniform memory access (NUMA) domain in the sense that the domains have different predicted levels of reliability and/or RAS capabilities. NUMA typically refers to distance and/or speed of access, where slower or faster memories are exposed to applications. Unlike typical NUMA, RAS based NUMA domains expose different memory regions or domains with different observed or predicted error rates. Thus, unlike conventional NUMA in which speed and distance characteristics are considered static, reliability and error rates can change. Therefore, in one example, RAS based NUMA domains are dynamically maintained to account for the changes in observed or predicted reliability of different memory regions.

In one example, memory regions or domains are categorized (e.g., through prediction) and carved out that are less likely to fail and more likely to fail, and exposed (e.g., as different reliability flags in the RAS-based memory domains). Note that domains do not necessarily have physically contiguous addresses within the domain; thus, hardware and/or software tracks address mapping for the different RAS-based memory domains. Further, RAS mitigation mechanisms like Adaptive Double DRAM Device Correction (ADDDC) and aggressive usage of ECC can be implemented in domains where it is desired to guarantee a higher RAS capability.

In order to take advantage of different RAS-based memory domains, in one example, applications can request higher or lower reliability memory when allocating memory. For example, while making an mmap( )or malloc( )function call, applications can pass a bit or flag specifying to the hardware that a given memory region is critical or non-critical from a RAS/reliability perspective. Adding a field or flag to memory allocation functions gives the OS and HW a hook to manage the RAS-based memory domains to ensure that critical memory regions (such as regions 204A and 204B of FIG. 2) in the applications' usage/address space reside in memory that is least likely to fail.

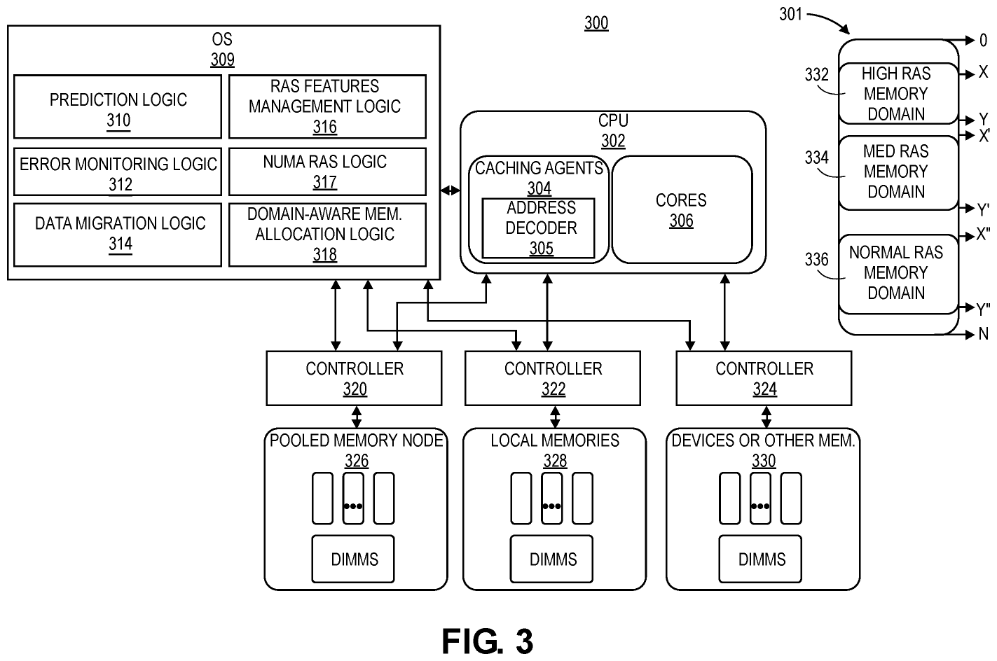

In one example, the operating system manages the RAS-based memory domains. For example, FIG. 3 is a block diagram of a system 300 in which RAS-based memory domains can be implemented. The system (or platform) 300 includes processing and memory resources that can be distributed, within the same physical system, or a combination of resources within a physical system and distributed resources. The system 300 includes a central processing unit (CPU) 302, which includes processor cores 306. In one example, the CPU 302 represents computing or processing resources for the system 300 and can be understood generally as the component to execute an operating system 309 that will manage a software environment to control the operation of the system 300. The CPU 302 can represent any type of microprocessor, CPU, graphics processing unit (GPU), infrastructure processing unit (IPU), processing core, or other processing hardware to provide processing for compute platform, or a combination of processors. The CPU 302 controls the overall operation of the system 300, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

The CPU 302 includes one or more caching agents 304. The caching agent(s) include hardware logic (e.g., circuitry) to ensure cache coherency of the system 300. The CPU 302 coupled with memory resources including a pooled memory node 326, local memory 328, and other devices or memory 330. The pooled memory node (or a memory pool) 326 represents memory resources (e.g., typically remote memory resources) made available to the system 300. In one example, the pooled memory node 326 is a server (e.g., a memory server or memory node) with a large capacity of memory resources that are made available to other systems or servers. In one example, the pooled memory node 326 includes one or more pooled memory drawers/sleds/chassis in a rack to provide a memory pool. In one example, the pooled memory node 326 is coupled with the CPU 302 via a Compute Express Link (CXL).

In the illustrated example, the system 300 also includes local memory 328 (such as DRAM DIMMs coupled with the CPU 302), and other memory 330. Other memory may include, for example, another processor's local memory, or other memory that is accessible by the CPU 302.

In the example illustrated in FIG. 3, the memory resources 326, 328, and 330 are coupled with the CPU 302 via controllers 320, 322, and 324, respectively. In one example, the controller 320 is a CXL controller in accordance with a CXL standard specification, such as CXL version 1.0 (released Mar. 11, 2019), CXL version 2.0 (released Nov. 10, 2020), CXL version 3.0 (released Aug. 2, 2022), or other version of CXL. In one example of pooled memory provided by one or more servers, the pooled memory node 326 is coupled with the CPU 302 via a network.

The local memory 328 is coupled with the CPU 302 via the controller 322. In one example, the controller 322 includes a DRAM memory controller. In one such example, controller 322 is an integrated memory controller (iMC) that is integrated into the CPU 302. Other memory devices 330 may also be coupled with the CPU via a controller 324. Although the system 300 depicts a controller for each of the memory resources 326, 328, and 330, in other examples, a system can include a single memory controller to control multiple memory resources. Additionally, although a single controller is shown for each of the memory resources 326, 328, and 330, it will be understood that different and/or additional components can couple the memory resources 326, 328, and 330 with the CPU 302 (e.g., fabric managers, switches, root ports, or other components).

The memory resources are mapped to a physical address range 301 to provide system memory for the system 300. In an example in which pooled memory makes up part of the system memory, the physical address range 301 is a distributed coherent address range (e.g., distributed CXL coherent address range). The example in FIG. 3 depicts three RAS-based memory domains: a high RAS memory domain 332, a medium RAS memory domain 334, and a normal RAS memory domain 336, where the high RAS memory domain 332 is associated with high reliability. In the example in FIG. 3, the high RAS memory domain 332 includes physical addresses X-Y, the medium RAS domain 334 includes physical addresses X′-Y′, and the normal RAS memory domain 336 includes physical addresses X″-Y″. In one example, memory resources that implement replication and advanced RAS features (e.g., higher ECC bits), and have a low observed failure rate are assigned to the high RAS memory domain 332. Memory resources that implement advanced RAS features and have a low observed failure rate are assigned to the medium RAS memory domain 334. The rest of memory media is assigned to the normal RAS memory domain 336. Each of the memory resources 326, 328, and 330 can include resources mapped to a single domain, or different memory ranges mapped to multiple domains. In one example, the pooled memory node can include media that is in the high and medium RAS memory domains 332, 334, and the local and other memory 328, 330 include media in the high and normal RAS memory domains 332, 336.

In one example, the operating system 309 includes prediction logic 310 to make predictions regarding the likelihood of errors in the memory resources 326, 328, and 330, error monitoring logic 312 to monitor errors in the memory resources 326, 328, and 330, RAS features management logic 316 to track RAS features of the memory resources 326, 328, and 330, and NUMA RAS logic 317 to determine which memory resources 326, 328, 330 to assign to the different RAS-based memory domains based on RAS capabilities and/or error monitoring. In one example, for the high and medium domains (both using advanced RAS features), the operating system monitors the occurrence of correctable errors being detected in the medias where those type of memory ranges are mapped. When those numbers surpass specific thresholds (e.g., configurable percentages or other thresholds) or prediction logic in the OS, memory, or the controllers indicate that there is a likelihood of uncorrectable errors, the operating system will remap and move these memory ranges to other medias (e.g., pooled memory or other memory available in the system) that have a lower percentage or rate of correctable errors. For example, data migration logic 314 can move data and trigger address remapping when a memory resource is moved to a different domain.

To enable applications to take advantage of the RAS-based memory domains, in one example, the operating system and CPU offer a new interface that allows to the software stacks to allocate memory regions with certain reliability. For example, the OS 309 includes domain-aware memory allocation logic 318 to enable applications to allocate memory in the high RAS memory domain 332 for critical data. For example, the operating system provides a new type of allocation function (such as malloc( ) or mmap( )) or type of API (application programming interface) that allows applications to specify what type of RAS memory domain the allocated memory range should be mapped to. In one such example, the parameter is a reliability flag, or RAS memory domain flag or field, that enables applications to request memory with high reliability. A reliability or RAS memory domain parameter can also be added to existing APIs.

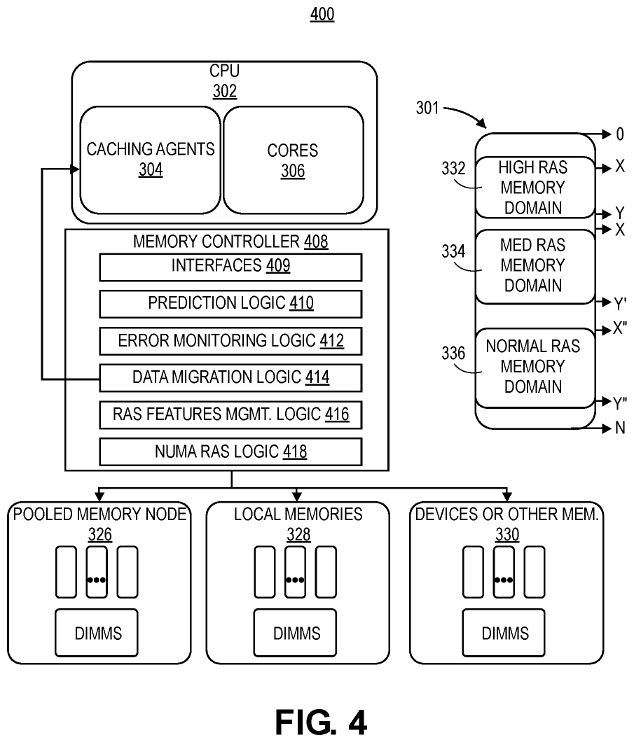

Although FIG. 3 depicts the RAS memory domain logic as being implemented primarily in the operating system, some or all of the RAS memory domain logic can be implemented in hardware. FIG. 4 depicts a block diagram of a system 400 in which some of the RAS memory domain logic is implemented primarily in a memory controller 408. Note that although the example in FIG. 4 depicts a single memory controller 408 between the CPU 302 and the memory resources 326, 328, and 330, additional controllers or other components may couple the memory resources 326, 328, 330 with the CPU via the memory controller 408. The memory controller 408 can be discrete or integrated with the CPU 302.

The memory controller 408 includes input/output (1/0) interface circuitry 409 to enable the memory controller 408 to interface with the memory resources 326, 328, and 330, the CPU 302. In the example illustrated in FIG. 4, the memory controller 408 includes prediction logic 410 to make predictions regarding the likelihood of uncorrectable errors in the memory resources 326, 328, and 330, error monitoring logic 412 to monitor errors in the memory resources 326, 328, and 330, data migration logic 414 to handle data movement and address remapping when a memory resource is reclassified into a different RAS-based memory domain, RAS features management logic 416 to track RAS features of the memory resources 326, 328, and 330, and NUMA RAS logic 418 to determine which memory resources 326, 328, 330 to assign to the different RAS-based memory domains based on RAS capabilities and/or error monitoring. Regardless of whether the functionality is implemented in a memory controller or an operating system, the memory resources are classified into RAS-based memory domains based on the likelihood of errors in the memory resources.

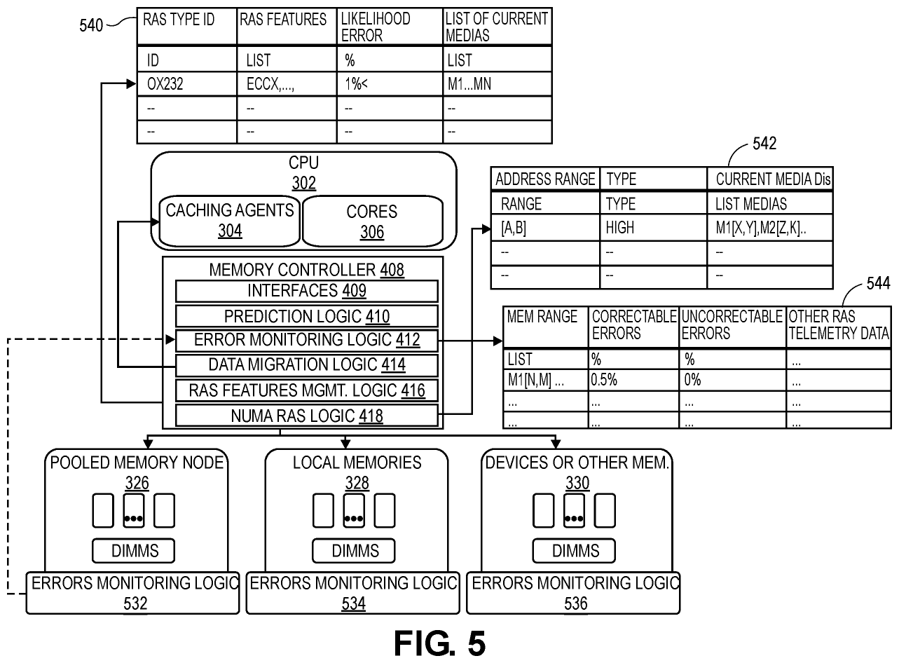

FIG. 5 is a block diagram of a system in which RAS-based memory domains can be implemented, including examples of data and mapping information used to implement the domains. Depending on the implementation, one or more of the caching agents 304, memory controller 408, and operating system are updated to comprehend the RAS-based memory domains. For example, as illustrated in FIG. 5, the table 542 represents the mapping of physical addresses to RAS-based memory domains and memory resources 326, 328, and 330. The table 542 includes an address range (e.g., a physical address range), the “type” of memory, and the memory resources that are currently mapped to those address ranges. The “type” indicates the RAS-based memory domain. As mentioned above, two or more RAS-based memory domains can be implemented to classify memory having different levels of reliability, such as a high, medium, and normal (e.g., lower than medium reliability). The memory media mapped to the physical address ranges can be from multiple different memory resources and can include parts or all of a given memory resource. For example, only part of each of the memory resources 326, 328, and 330 are classified in the high RAS memory domain. Referring again to the table 542, as an example, the physical address range [A,B] is in the high RAS memory domain, and the device address range [X,Y] of the memory resource M1 and the device address range [Z,K] of the memory resource M2 are mapped to that physical address range.

The actual mapping and RAS-based domain information can be implemented in the address decoding logic in the caching agents and the memory controller, in the operating system, or in a combination of hardware and the operating system. In one example, a set of new bits of the system address decoder (e.g., address decoder 305 in the caching agents 304/CPU 302) and address decoder of the memory controller 408 to understand what system physical address ranges in the CPU domain are mapped into a specific ranges for the RAS-based memory domains. In one example, the system address decoder and the physical address decoder do not need to include additional bits to indicate which RAS-based domains the physical addresses are mapped to, and instead, the operating system tracks which RAS-based memory domains the physical address ranges are in. For example, the page tables can include the type of RAS memory domain that they are mapped to and may also track replication. In another example, both the operating system and hardware track which physical address ranges correspond to which RAS-based memory domains.

In addition to tracking which physical address ranges correspond to which RAS-based memory domains, in one example, the RAS capabilities of the memory resources are identified and used to determine which domain to assign the memory resources to. For example, the table 540 is an example of RAS feature data tracked for the memory resources. In the example illustrated in FIG. 5, a “RAS type ID” or reliability level can be used to identify memory resources with the same or similar RAS capabilities. For example, the reliability level could be high, medium, and low/normal, or some other number of discrete levels indicating different reliability. A RAS type or reliability level ID can be a value (e.g., one or more bits) that corresponds to a RAS-based memory domain. For example, the value “0×232” may correspond to a high RAS memory domain.

In one example, a list of available RAS features that can be configured and/or a list of potential knobs (e.g., configurable options) for each RAS feature is tracked. Examples of RAS features include, error correction code (ECC) capabilities, single device data correction (SDDC), adaptive double DRAM device correction (ADDDC), advanced error detection and correction (AEDC), local machine check exceptions (LMCE), sparing, memory mirroring, and other RAS features. Examples of RAS feature configurable options (e.g., include enabling or disabling RAS features, the granularity at which features are supported, and other configurable options. In one example, each RAS feature can be enabled or disabled, and some RAS features may include other configurable options, such as the granularity at which the feature is applied. RAS features help mitigate reliability problems. Thus, memory with higher reliability (higher RAS) is less likely to need RAS features enabled; conversely RAS features are critical for memory with poor reliability (lower RAS).

Different RAS features can have different levels of complexity and effectiveness, and logic in the memory controller and/or operating system (e.g., the RAS feature management logic 416 and/or prediction logic 410 of FIGS. 4 and 5 or similar logic in the operating system as in FIG. 3) can determine the likelihood of errors in the memory media based on the current RAS capabilities and configurations. In one example, the memory controller includes an interface (e.g., one of the interfaces 409) that allows the operating system, BIOS, or any other system component to register a memory resource and its RAS capabilities by providing the RAS features and configurations. The information can then be stored (e.g., in one or more registers in the memory controller or elsewhere in the platform or in memory) and used to determine the likelihood of errors in the memory resource.

In addition to determining the likelihood of errors in a memory resource based on the RAS features and configurations, actual observed errors and other RAS telemetry data can be used to determine the likelihood of errors in a memory resource. For example, error monitoring logic in the memory controller and/or operating system (e.g., error monitoring logic 412 of FIGS. 4 and 5 and error monitoring logic 312 of FIG. 3) can monitor errors in the memory resources to determine if the likelihood of errors has changed sufficiently to move the resource to a different RAS-based domain. In one example, the memory controller includes an interface (e.g., one the interfaces 409) to allow for the various media (e.g., memory resources 326, 328, and 330) in the system to provide feedback regarding the current observed correctable and uncorrectable failures. For example, error monitoring logic for each memory resource (e.g., error monitoring logic 532, 534, and 536) detect and report errors to the memory controller. The memory controller can then track those errors and/or communicate the error information to the operating system. In one such example, not all medias may not use this functionality, but it may be desirable for some memory resources, such as for pooled memory or memory in other accelerators or discrete devices.

In one example, memory resources provide information regarding encountered errors including one or more of: the memory range or list of sub-medias (e.g., ranks) in which an error occurred, the current percentage of correctable errors, the current percentage of uncorrectable errors, and/or other types of RAS telemetry data. Error data can be stored by the memory controller and/or operating system and used by the prediction logic (e.g., prediction logic 410 of FIGS. 4 and 5 of prediction logic 310 of FIG. 3) to determine likelihood of errors in the memory range in view of the error data. Error data can be stored in registers in the memory controller 408 or elsewhere in the platform and/or in memory. For example, the table 544 represents error data, including the memory range, percentage of correctable errors, percentage of uncorrectable errors, and other RAS telemetry data. As an example, the memory range [N,M] in memory resource M1 has observed 0.5% correctable errors and 0% uncorrectable errors.

In one example, prediction logic (e.g., prediction logic 410 of FIGS. 4 and 5 of prediction logic 310 of FIG. 3) then processes the existing telemetry data provided by the memory resources or other components in the system to predict the potential likelihood of uncorrectable failures for each memory resource. In one example, the prediction logic implements machine learning (e.g., deep learning) algorithms to perform this projection. In one example, the prediction logic uses one or more of: the RAS feature and configurations data (e.g., the data in the table 540), observed error data (e.g., the data in the table 544), data provided by other logic such as patrol scrubbers or from the platform (e.g., temperature or other data from the platform) that is relevant to the reliability of the memory resources.

In one example, once a likelihood of failure is detected (or once there is a change in the likelihood of errors that exceeds a threshold), the information is provided to NUMA RAS logic 418 (e.g., the NUMA RAS logic 418 of FIGS. 4 and 5 or the NUMA RAS logic 317 of FIG. 3). In one example, the NUMA RAS logic provides an interface to the prediction logic to act on a prediction, and implements a flow when the RAS status of a media is to be changed (e.g., from a high to medium, or medium to low RAS memory domain). Consider an example in which there is a high RAS memory domain, a medium RAS memory domain, and a normal RAS memory domain. In one such example, there is replication and advanced RAS features (e.g., higher ECC bits) for the high RAS memory domain, and advanced RAS features for the medium RAS memory domain. In one such example, for the high and medium domains, the memory controller 408 and/or operating system monitor the occurrence of correctable errors being detected in the medias where those type of memory ranges are mapped. When those numbers surpass specific percentages (e.g., a configurable threshold) or if prediction logic asserts a signal (such as the prediction logic asserting one or more signals indicating the likelihood of uncorrectable errors), these memory ranges are remapped and moved to other medias (e.g., pooled memory or other memory available in the system) in the desired RAS-based domain. In one such example, if the remapping cannot be accomplished (e.g., due to insufficient resources), the memory controller can generate a system interrupt to notify the operating system.

In one example, when media is moved to a lower RAS-based memory domain due to media becoming less reliable, data may need to be moved in addition to reconfiguring the mapping of physical addresses to memory resources. Depending on implementation, remapping of memory ranges and data migration can be triggered by the operating system or the memory controller. In one example, the memory controller 408 includes an interface (e.g., one of the interfaces 409) that allows the memory controller to specify that a memory range is moved from one media(s) to another media(s) because there is a likelihood the media is becoming less resilient and memory ranges in the high and medium RAS memory domains that are mapped there need to be moved. In one such example, such an interface allows the memory controller to provide a memory range or a list of memory ranges being remapped (e.g., in case of interleaving across multiple DIMMS), and the new media mapped into each memory range. During the data movement, the caching agents 304 can block accesses to those regions and unblock and execute the accesses once the memory controller 408 acknowledges that data has been moved. Alternatively, as data gets moved, the memory controller can provide this feedback to the caching agents, which may be a beneficial approach when large data blocks are being moved.

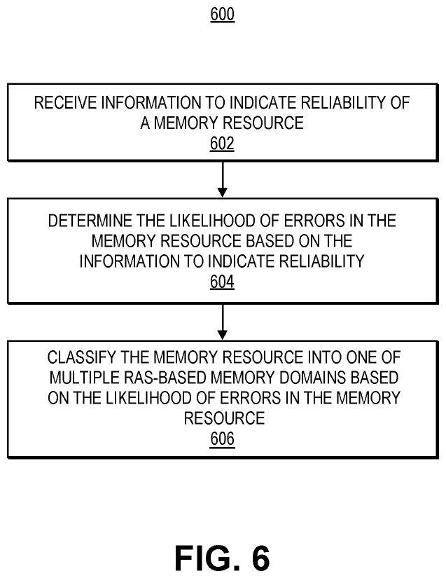

FIGS. 6-9 are flow diagrams of examples of methods for implementing RAS-based memory domains. The methods of FIGS. 6-9 can be implemented in hardware (e.g., hardware logic of one or more memory controllers, processors, or other hardware), firmware, software (e.g., an operating system, virtual machine manager (VMM), or other software), or a combination of hardware, firmware, and/or software.

Turning first to FIG. 6, the method 600 begins with receiving information indicative of reliability of a memory resource, at block 602. Receiving information indicative of reliability of a memory resource can include, for example, receiving information related to errors encountered in the memory resource (e.g., correctable or uncorrectable errors, the location of the errors, and/or other information related to errors in the memory resource), RAS capabilities and current configurations for the memory resource, and other information that may indicate or affect the reliability of memory, such as temperature data (e.g., temperature data at the device, package or platform level). In an example in which the memory resource is coupled with the CPU via a networked (e.g., in the case of a pooled memory), data regarding network errors can also be indicative of errors in the network-attached memory resource. The information can be for an entire memory resource (e.g., an entire device, module, or pool) or for a portion of the memory resource (e.g., one or more pages or locations, ranks, or other granularities).

The information to indicate reliability of the memory resource can be received in response to the memory resource being added as an available memory resource to the system (e.g., in response to the memory resource being hot plugged into the system or otherwise added to the system), or in response to some other trigger, such as an error being encountered, an error metric exceeding a threshold, a temperature metric exceeding a threshold, or some other trigger. Referring to FIG. 3, in one example in which the method 600 is implemented in software (e.g., by the operating system 309), the error monitoring logic 312 receives error information from a controller for the memory resource (e.g., controllers 320, 322, and 324 for memory resources 326, 328, and 330, respectively). In one such example, the RAS features management logic 316 receives information about RAS features and configurations from the controller for the memory resource. Referring to FIG. 4, in one example in which the method 600 is implemented in hardware (e.g., by the memory controller 408), error monitoring logic 412 receives error information from the memory resources 326, 328, and 330. Similarly, the RAS features management logic 416 receives information about RAS features and configurations from the memory resources 326, 328, and 330.

Referring again to FIG. 6, the method 600 involves determining the likelihood of errors in the memory resource based on the information to indicate reliability, at block 604. For example, prediction logic in a controller or in the operating system (e.g., the prediction logic 310 of FIG. 3 or prediction logic 410 of FIG. 4) can predict the likelihood of errors in the memory resource based on one or more factors including: the RAS capabilities and settings of the memory resource, the occurrence of errors in the memory resource, temperature data, or other data indicative of reliability.

The method then involves classifying the memory resource into one of multiple RAS-based memory domains based on the likelihood of errors in the memory resource, at block 606. For example, NUMA RAS logic (e.g., the NUMA RAS logic 317 of FIG. 3 or NUMA RAS logic 418 of FIG. 4) classifies the memory resource into a RAS-based domain. In one example, classifying the memory resource into a RAS-based domain involves updating page tables, mapping logic, or both to identify the memory resource as belonging to the assigned RAS-based domain. For example, a field or flag in an entry of a page table can be updated to indicate the domain, and/or one or more bits can be added to the mapping logic in the CPU and controllers.

The RAS-based memory domains include at least two domains, where one RAS memory domain represents higher reliability or RAS than the other (e.g., a higher RAS memory domain and a lower RAS memory domain, where the lower RAS memory indicates reliability relative to the higher RAS memory domain and not necessarily low RAS capabilities). As illustrated in FIGS. 3 and 4, in one example, there are three RAS memory domains (high, medium, and normal RAS memory domains). However, this disclosure is not limited to two or three RAS memory domains; other examples can include more than three RAS memory domains (e.g., 4, 5, 10, etc.). The RAS memory domains can then be used to enable software to selectively allocate memory in high reliability memory. In one example, the RAS memory domains are not static, but can be adjusted dynamically to reflect the changing reliability of the memory resources.

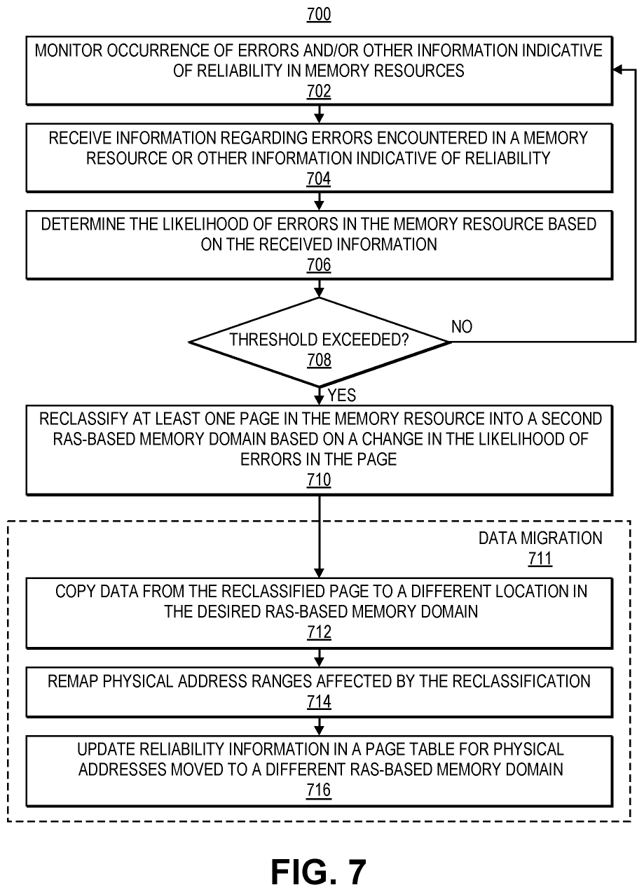

For example, FIG. 7 illustrates a flow diagram of a method 700 of dynamically maintaining the RAS-based memory domains. The method 700 illustrates additional aspects of implementing RAS-based memory domains related to error monitoring, RAS memory domain reconfiguration, and data migration. The method 700 begins with monitoring the occurrence of errors and/or other information indicative of reliability in memory resources, at block 702. For example, error monitoring logic (e.g., error monitoring logic 312 of FIG. 3 or error monitoring logic 412 of FIG. 4) can monitor the memory resources for correctable and/or uncorrectable errors. In one example, resources assigned to or classified into only the highest RAS-based memory domain(s) are monitored for errors to determine if those memory ranges should be downgraded or reclassified into a lower reliability RAS memory domain. For example, only the highest or all but the lowest reliability domains are monitored for potential reclassification into lower RAS memory domains. In another example, memory resources in all the RAS memory domains are monitored for errors.

While monitoring the memory resources for errors, the method 700 involves receiving information regarding errors encountered in a memory resource or other information indicative of reliability, at block 704. For example, error monitoring logic (e.g., the error monitoring logic 312 of FIG. 3 or error monitoring logic 412 of FIG. 4) receives information indicating one or more errors were encountered and other information related to the errors, such as the location of the errors (e.g., address range, page, device, rank, or other granularity). The method then involves determining the likelihood of errors in the memory resource based on the new information, at block 706. If a threshold is not exceeded, 708 NO branch, error monitoring continues at block 702. If a threshold is exceeded, 708 YES branch, the newly received information indicative of reliability suggests the likelihood of errors increased sufficiently to reclassify the memory resource into a second RAS-based memory domain, at block 710. For example, NUMA RAS logic (e.g., the NUMA RAS logic 317 of FIG. 3 or NUMA RAS logic 418 of FIG. 4) determines that the memory resource should be reclassified to a lower RAS memory domain.

After reclassifying a memory resource to a lower RAS memory domain, data migration 711 may be needed to ensure the data at the reclassified memory locations is moved to a sufficiently reliable location. For example, data migration logic (e.g., data migration logic 314 of FIG. 3 and/or data migration logic 414 of FIG. 4) handles any necessary data movement and remapping due to the reclassification. For example, the data is copied (moved) from the reclassified pages to a different location in the desired RAS-based memory domain, at block 712. The method involves remapping physical address ranges affected by the reclassification, at block 714. For example, physical addresses previously mapped to memory resources that have been downgraded to a lower RAS memory domain may need to be remapped to resources in the higher RAS memory domain (which enables a contiguous physical address range to be maintained for a domain). Similarly, other physical addresses may need to be moved to the lower RAS memory domain, and remapped to the reclassified memory resources.

The method 700 also involves updating reliability information (e.g., a field or flag indicating the RAS memory domain) in a page table for physical addresses moved to a different RAS-based memory domain, at block 716. For example, in an implementation in which the page tables include one or more bits to indicate which RAS memory domain a physical page is in, when the physical page is moved to a different domain, the operating system updates the page table entry for that physical page to reflect the reclassification.

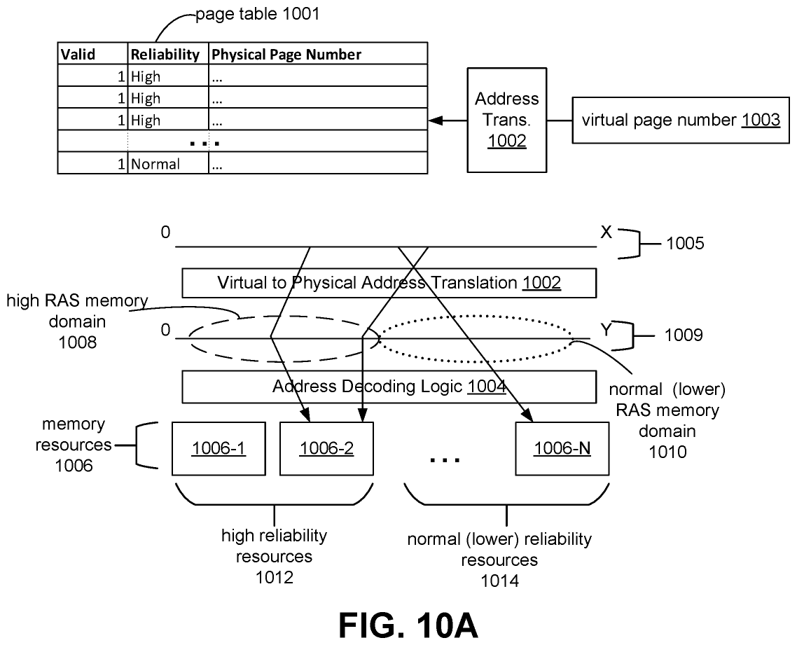

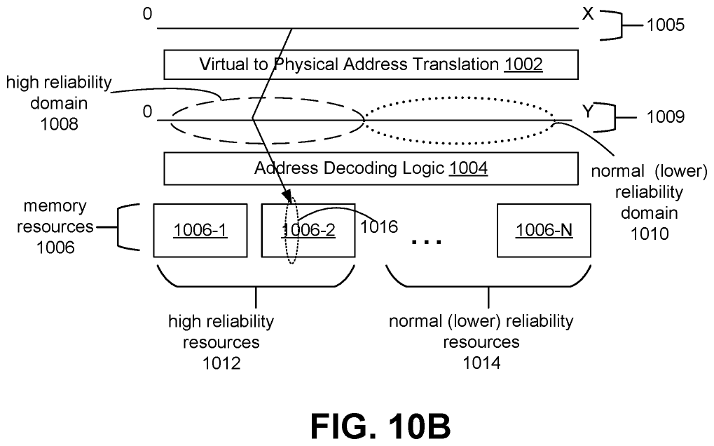

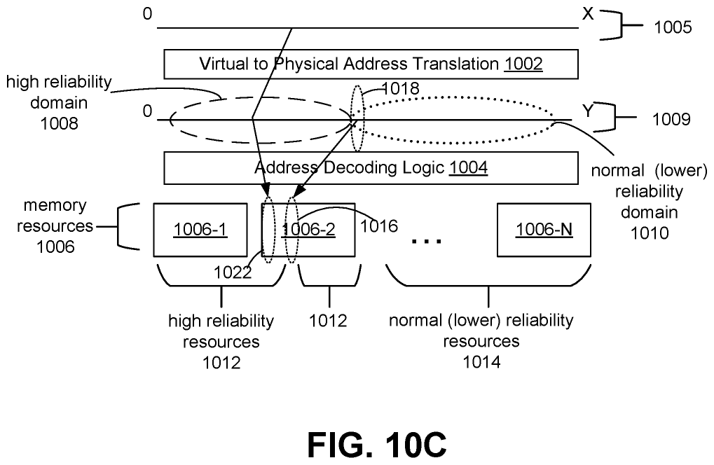

FIGS. 10A-10C illustrate an example of reclassification of a memory range from a high RAS memory domain to a lower RAS normal (lower) RAS memory domain. FIG. 10A illustrates a mapping of virtual address space 1005 to physical address space 1009, and a mapping of physical address space 1009 to the device addresses of memory resources 1006. Address translation logic 1002 in an operating system takes a virtual page number 1003 and translates it to a physical page number (or page frame number) in a page table 1001. Note that the page table 1001 includes one or more bits to indicate reliability. In the example illustrated in FIG. 10A, the first three physical page numbers shown are classified in a high RAS memory domain, and the last depicted physical page number is classified into a normal RAS memory domain. Address decoding logic 1004 (e.g., in the CPU and the memory controller) decodes the physical address to determine the device address in one of the memory resources 1006.

The physical address space 1009 is assigned or classified into RAS memory domains. In the example of FIG. 10A, the address range 1008 is in a high RAS memory domain, and the address range 1010 is in a normal RAS memory domain with lower reliability than the high RAS memory domain. Memory resources 1012 determined to have high reliability (e.g., based initially on RAS features and configurations) are mapped into the address range 1008 in the high RAS memory domain. Memory resources 1014 determined to be less reliable are mapped to the address range 1010 in the normal RAS memory domain.

Referring to FIG. 10B, consider an example in which a region 1016 in memory resources 1012 initially classified into the high RAS domain encounter a burst of failures. In this example, prediction logic (e.g., the prediction logic 310 of FIG. 3 or prediction logic 410 of FIG. 4) can identify this region 1016 as having a high likelihood of errors sufficient to trigger moving the memory range of region 1016 to a lower RAS memory domain. Once the region 1016 is moved to a lower RAS memory domain, in one example, the data stored in those locations may need to be moved to a high RAS memory domain. For example, referring to FIG. 10C, the data stored in the reclassified region 1016 is moved to another location 1022 in the high reliability domain. In this example, the mapping is also reconfigured. For example, to maintain a contiguous physical address range in the high RAS domain, the physical addresses 1018 at one end of the high RAS domain are reclassified into the normal RAS memory domain, and mapping in the CPU and memory controller is be updated to reflect affected memory ranges. For example, the physical addresses 1018 now in the normal RAS memory domain are remapped to the reclassified region 1016, and physical addresses in the high RAS memory domain are remapped to the locations 1022 to where the data was moved in the high reliability memory resources 1012. In this example, the page table is updated for physical pages in the region 1018 moved to the normal RAS memory domain. For example, a reliability flag for the page table entries for pages in the region 1018 are updated from high to normal reliability. In this example, the virtual to physical address mapping did not need to be updated, however, in other examples, the virtual to physical address mapping and reliability flags in the page table may need to be updated.

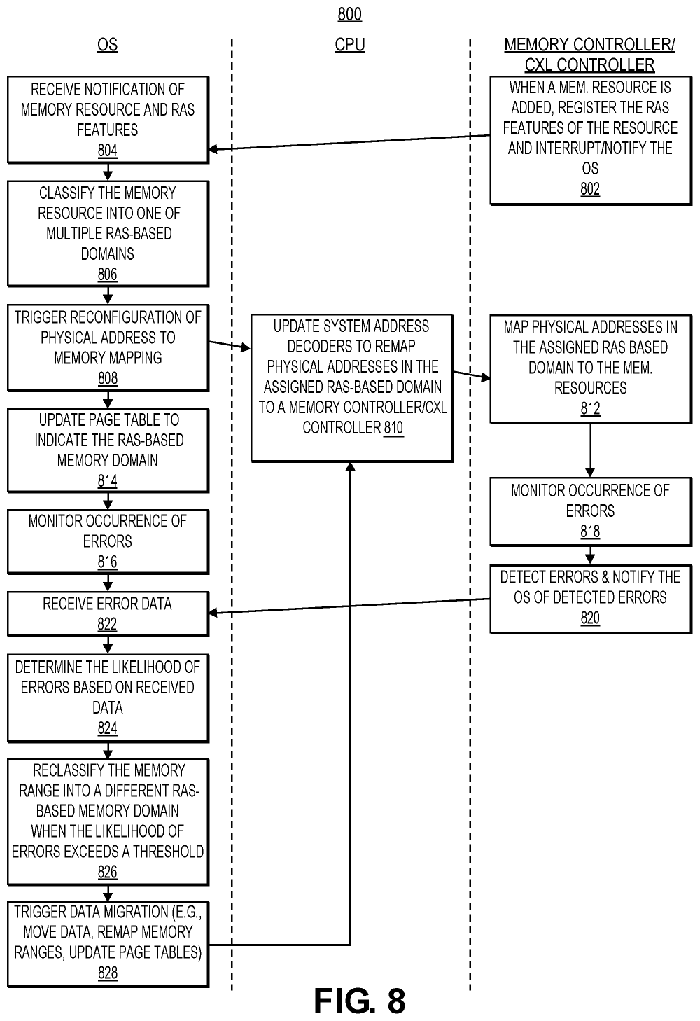

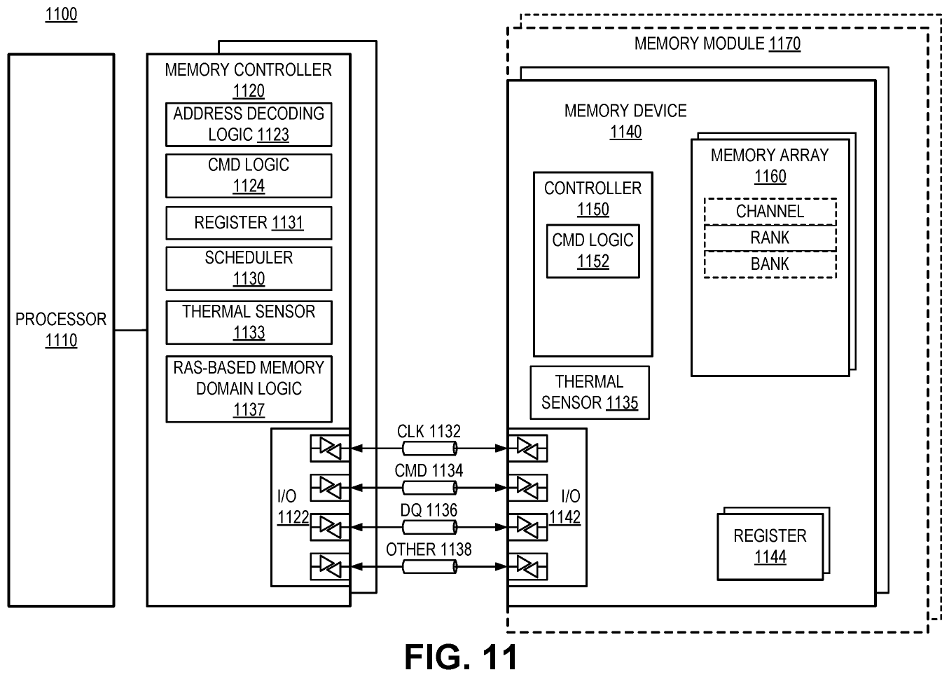

FIG. 8 is a flow diagram of an example of a method 800 for implementing RAS-based memory domains in which the RAS NUMA logic is implemented in the operating system. In the example in FIG. 8, operations in the operating system, CPU, and a controller (e.g., memory controller, CXL controller, or other control logic) are shown. The operating system, CPU, and controller are in accordance with examples described herein (for example, the operating system 309, CPU 302, and controllers 320, 322, and 324 of FIG. 3, the controller 408 of FIG. 4, and the memory controller 1120 and processor 1110 of FIG. 11).

The method 800 begins when a memory controller detects that a memory resource is added to the system (e.g., hot plugged), at block 802. The memory controller registers the RAS features of the newly added memory resource and notifies the operating system of the RAS features (e.g., by interrupting the operating system). The operating system receives notification of the memory resource and its RAS features, at block 804. The operating system classifies the memory resource into one of multiple RAS-based domains, at block 806. The operating system triggers reconfiguration of physical address-to memory mapping, at block 808. For example, the operating system causes the CPU to update system address decoders to remap physical addresses in the assigned RAS-based domain to a memory controller/CXL controller, at block 810, and the memory controller or CXL controller to map physical addresses in the assigned RAS-based memory domain to the memory resources, at block 812.

The operating system updates page tables so that the entries for physical pages mapped to the newly added memory resources indicate the assigned RAS-based memory domain, at block 814. The memory controller and operating system monitor the occurrence of errors, at blocks 816 and 818. When the memory controller detects an error, it notifies the operating system of the detected errors, at block 820. The operating system receives the error data, at block 822, and determines the likelihood of errors based on the received data, at block 824. If the likelihood of errors exceeds a threshold, the operating system reclassifies the memory range with the errors into a different RAS-based domain, at block 826. The operating system then triggers data migration and remapping, at block 828. For example, the operating system causes data to be moved from the reclassified locations into locations in the higher RAS memory domain, remap affected memory ranges (e.g., by updating system address decoders at block 810 and mapping in the memory or CXL controllers at block 812), and update page tables as needed.

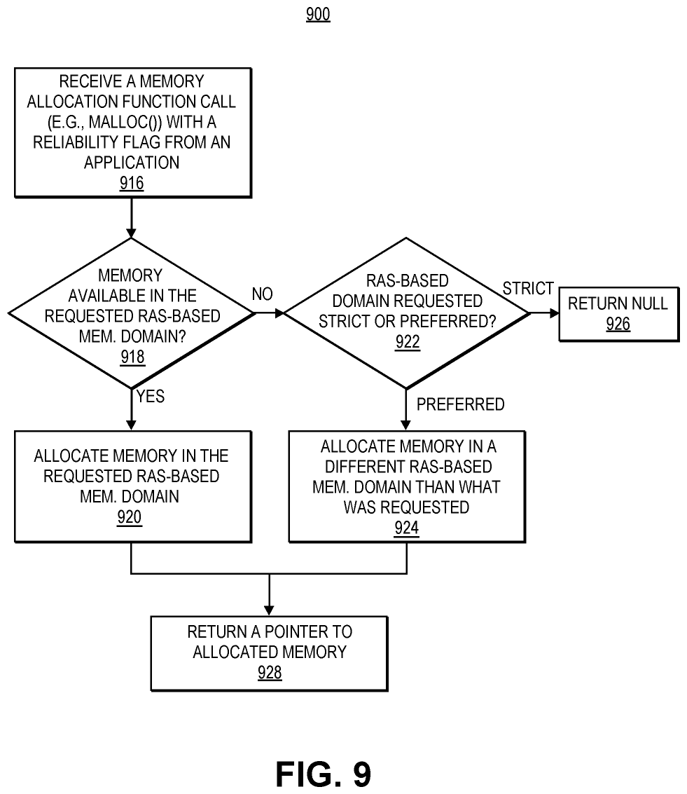

FIG. 9 is a flow diagram of an example of RAS memory domain-aware memory allocation. The method 900 is implemented in an operating system or other software responsible for allocating memory. The method 900 begins with the receiving a memory allocation function call with a reliability flag from an application, at block 916. For example, an operating system receives a malloc( ) mmap( ) or other function call requesting memory allocation. The request includes a flag or parameter indicating the requested reliability (e.g., high or normal reliability, a value identifying a specific RAS based-memory domain, or other reliability parameter).

The request can also include a parameter to indicate whether the requested reliability is strict or preferred. In one such example, a memory allocation request with a strict reliability request will return NULL (or another value to indicate failure to allocate memory with the requested reliability) if memory in the requested RAS-based memory domain is unavailable. In one such example, a memory allocation request with a preferred reliability request can allocate memory in a non-preferred RAS-based memory domain if memory in the preferred RAS-based memory domain is unavailable. For example, consider a request that is received to allocate memory with parameters indicating “high reliability” and “preferred.” If the operating system is unable to allocate memory in the highest RAS memory domain, the operating system can attempt to allocate memory in the next highest RAS memory domain, and so forth, until the operating system is able to allocate memory.

Referring again to FIG. 9, if memory is available in the requested RAS-based memory domain, block 918 YES branch, the operating system allocates memory in the requested RAS-based memory domain, at block 920, and returns a pointer to the allocated memory, at block 928. If memory is not available in the requested RAS-based memory domain, block 918 NO branch, the operating system checks if the request is strict or preferred. If the request is strict (at block 922 “strict” branch), the operating system returns NULL, at block 926. If the request is preferred (at block 922 “preferred” branch”), the operating system allocates memory in a different RAS-based memory domain than what was requested, at block 924, and returns a pointer to the allocated memory, at block 928.

Thus, the methods in FIGS. 6-9 illustrate examples of methods for implementing RAS-based memory domains. Exposing different domains to software enables software to intelligently allocate memory with high reliability for critical data to improve system performance and reduce downtime.

FIG. 11 is a block diagram of an example of a memory subsystem in which RAS-based memory domains can be implemented. The system 1100 includes a processor and elements of a memory subsystem in a computing device.

The processor 1110 represents a processing unit of a computing platform that may execute an operating system (OS) and applications, which can collectively be referred to as the host or the user of the memory. The OS and applications execute operations that result in memory accesses. The processor 1110 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory accesses may also be initiated by devices such as a network controller or hard disk controller. Such devices can be integrated with the processor in some systems or attached to the processer via a bus (e.g., PCI express), or a combination. The system 1100 can be implemented as an SOC (system on a chip), or be implemented with standalone components. The system of FIG. 11 is one example of a system in which RAS-based memory domains can be implemented. Other systems with different or additional components may implement a RAS-based memory domains.

Reference to memory devices can apply to different memory types. Memory devices often refers to volatile memory technologies. Volatile memory is memory whose state (and therefore the data stored on it) is indeterminate if power is interrupted to the device. Nonvolatile memory refers to memory whose state is determinate even if power is interrupted to the device. Dynamic volatile memory requires refreshing the data stored in the device to maintain state. One example of dynamic volatile memory includes DRAM (dynamic random access memory), or some variant such as synchronous DRAM (SDRAM). A memory subsystem as described herein may be compatible with a number of memory technologies, such as DDR4 (Double Data Rate version 4, initial specification published in September 2012 by JEDEC (Joint Electronic Device Engineering Council)), DDR4E (DDR version 4), LPDDR3 (Low Power DDR version 3, JESD209-3B, August 2013 by JEDEC), LPDDR4 (LPDDR version 4, JESD209-4, originally published by JEDEC in August 2014), WIO2 (Wide Input/Output version 2, JESD229-2 originally published by JEDEC in August 2014), HBM (High Bandwidth Memory, JESD325, originally published by JEDEC in October 2013), DDR5 (DDR version 5, JESD79-5A, published October, 2021), DDR version 6 (DDR6) (currently under draft development), LPDDR5, HBM2E, HBM3, and HBM-PIM, or others or combinations of memory technologies, and technologies based on derivatives or extensions of such specifications. The specification for LPDDR6 is currently under development. The JEDEC standards are available at www.jedec.org.

In addition to, or alternatively to, volatile memory, in one example, reference to memory devices can refer to a nonvolatile memory device whose state is determinate even if power is interrupted to the device. A memory device can include a three dimensional crosspoint memory device, or other byte addressable nonvolatile memory devices. A memory device can include a nonvolatile, byte addressable media that stores data based on a resistive state of the memory cell, or a phase of the memory cell. In one example, the memory device can use chalcogenide phase change material. In one example, the memory device can be or include single or multi-level phase change memory (PCM) or phase change memory with a switch (PCMS), a resistive memory, nanowire memory, ferroelectric transistor random access memory (FeTRAM), magnetoresistive random access memory (MRAM) memory that incorporates memristor technology, or spin transfer torque (STT)-MRAM, or a combination of any of the above, or other memory.

The memory controller 1120 represents one or more memory controller circuits or devices for the system 1100. In one example, the memory controller 1120 is part of host processor 1110, such as logic implemented on the same die or implemented in the same package space as the processor. The memory controller 1120 represents control logic that generates memory access commands in response to the execution of operations by the processor 1110. The memory controller 1120 accesses one or more memory devices 1140. The memory devices 1140 can be DRAM devices in accordance with any referred to above. In one example, the memory devices 1140 are organized and managed as different channels, where each channel couples to buses and signal lines that couple to multiple memory devices in parallel. Each channel is independently operable. Thus, each channel is independently accessed and controlled, and the timing, data transfer, command and address exchanges, and other operations are separate for each channel. Coupling can refer to an electrical coupling, communicative coupling, physical coupling, or a combination of these. Physical coupling can include direct contact. Electrical coupling includes an interface or interconnection that allows electrical flow between components, or allows signaling between components, or both. Communicative coupling includes connections, including wired or wireless, that enable components to exchange data.

The memory controller 1120 includes registers 1131. The registers 1131 represent one or more storage devices or storage locations that provide configuration or settings for the operation of the memory device. In one example, the registers 1131 include one or more registers that can be initialized or otherwise programmed to store data related to RAS-based memory domains as described herein. In one example, settings for each channel are controlled by separate mode registers or other register settings. In one example, each memory controller 1120 manages a separate memory channel, although system 1100 can be configured to have multiple channels managed by a single controller, or to have multiple controllers on a single channel.

The memory controller 1120 includes I/O interface logic 1122 to couple to a memory bus, such as a memory channel as referred to above. The I/O interface logic 1122 (as well as I/O interface logic 1142 of memory device 1140) can include pins, pads, connectors, signal lines, traces, or wires, or other hardware to connect the devices, or a combination of these. The I/O interface logic 1122 can include a hardware interface. As illustrated, the I/O interface logic 1122 includes at least drivers/transceivers for signal lines. Commonly, wires within an integrated circuit interface couple with a pad, pin, or connector to interface signal lines or traces or other wires between devices. The I/O interface logic 1122 can include drivers, receivers, transceivers, or termination, or other circuitry or combinations of circuitry to exchange signals on the signal lines between the devices. The exchange of signals includes at least one of transmit or receive. While shown as coupling the I/O 1122 from memory controller 1120 to the I/O 1142 of the memory device 1140, it will be understood that in an implementation of the system 1100 where groups of memory devices 1140 are accessed in parallel, multiple memory devices can include I/O interfaces to the same interface of the memory controller 1120. In an implementation of the system 1100 including one or more memory modules 1170, the I/O 1142 can include interface hardware of the memory module in addition to interface hardware on the memory device itself. Other memory controllers 1120 will include separate interfaces to other memory devices 1140.

The bus between memory controller 1120 and memory devices 1140 can be implemented as multiple signal lines coupling memory controller 1120 to memory devices 1140. The bus may typically include at least clock (CLK) 1132, command/address (CMD) 1134, and write data (DQ) and read data (DQ) 1136, and zero or more other signal lines 1138. In one example, a bus or connection between memory controller 1120 and memory can be referred to as a memory bus. In one example, the memory bus is a multi-drop bus. The signal lines for CMD can be referred to as a “C/A bus” (or ADD/CMD bus, or some other designation indicating the transfer of commands (C or CMD) and address (A or ADD) information) and the signal lines for write and read DQ can be referred to as a “data bus.” In one example, independent channels have different clock signals, C/A buses, data buses, and other signal lines. It will be understood that in addition to the lines explicitly shown, a bus can include at least one of strobe signaling lines, alert lines, auxiliary lines, or other signal lines, or a combination.

The memory devices 1140 represent memory resources for system 1100. In one example, each memory device 1140 is a separate memory die. In one example, each memory device 1140 can interface with multiple (e.g., 2) channels per device or die. Each memory device 1140 includes I/O interface logic 1142, which has a bandwidth determined by the implementation of the device (e.g., x16 or x8 or some other interface bandwidth). The I/O interface logic 1142 enables the memory devices to interface with the memory controller 1120. I/O interface logic 1142 can include a hardware interface, and can be in accordance with the I/O 1122 of the memory controller, but at the memory device end.

In one example, memory devices 1140 are disposed directly on a motherboard or host system platform (e.g., a PCB (printed circuit board) on which processor 1110 is disposed) of a computing device. In one example, memory devices 1140 can be organized into memory modules 1170. In one example, memory modules 1170 represent dual inline memory modules (DIMMs). In one example, memory modules 1170 represent other organization of multiple memory devices to share at least a portion of access or control circuitry, which can be a separate circuit, a separate device, or a separate board from the host system platform. Memory modules 1170 can include multiple memory devices 1140, and the memory modules can include support for multiple separate channels to the included memory devices disposed on them. In another example, memory devices 1140 may be incorporated into the same package as memory controller 1120, such as by techniques such as multi-chip-module (MCM), package-on-package, through-silicon via (TSV), or other techniques or combinations. Similarly, in one example, multiple memory devices 1140 may be incorporated into memory modules 1170, which themselves may be incorporated into the same package as memory controller 1120. It will be appreciated that for these and other implementations, the memory controller 1120 may be part of the host processor 1110.

The memory devices 1140 each include one or more memory arrays 1160. The memory array 1160 represents addressable memory locations or storage locations for data. Typically, the memory array 1160 is managed as rows of data, accessed via wordline (rows) and bitline (individual bits within a row) control. The memory array 1160 can be organized as separate channels, ranks, and banks of memory. Channels may refer to independent control paths to storage locations within memory devices 1140. Ranks may refer to common locations across multiple memory devices (e.g., same row addresses within different devices) in parallel. Banks may refer to sub-arrays of memory locations within a memory device 1140. In one example, banks of memory are divided into sub-banks with at least a portion of shared circuitry (e.g., drivers, signal lines, control logic) for the sub-banks, allowing separate addressing and access. It will be understood that channels, ranks, banks, sub-banks, bank groups, or other organizations of the memory locations, and combinations of the organizations, can overlap in their application to physical resources. For example, the same physical memory locations can be accessed over a specific channel as a specific bank, which can also belong to a rank. Thus, the organization of memory resources will be understood in an inclusive, rather than exclusive, manner.

In one example, the memory devices 1140 include one or more registers 1144. The register 1144 represents one or more storage devices or storage locations that provide configuration or settings for the operation of the memory device. In one example, the register 1144 can provide a storage location for memory device 1140 to store data for access by memory controller 1120 as part of a control or management operation. In one example, the registers 1144 include one or more Mode Registers. In one example, the registers 1144 include one or more multipurpose registers. The configuration of locations within the registers 1144 can configure the memory device 1140 to operate in different “modes,” where command information can trigger different operations within memory device 1140 based on the mode. Additionally or in the alternative, different modes can also trigger different operation from address information or other signal lines depending on the mode. Settings of register 1144 can indicate configuration for I/O settings (e.g., timing, termination or ODT (on-die termination), driver configuration, or other I/O settings).

In one example, the registers 1144 include one or more registers that indicate a temperature of the memory device 1140, the memory module 1170, or both. For example, the register value can be indicative of a temperature of the memory device 1140 or memory module 1170 based on one or more thermal sensors on the memory device 1140 or memory module 1170 (e.g., the thermal sensor 1135). It can also indicate the temperature of thermal sensor 1133 on the processor or memory controller, temperature of one or more dies for stacked memory dies, a case temperature, or any other memory subsystem or system temperature. The controller 1150 of the memory device 1140 can sample the temperature from the thermal sensor and store a value representing the temperature, a range of temperatures, a temperature gradient, a change in temperature, or some other temperature information based on the reading of the thermal sensor. In one example, the thermal sensor(s) are sampled at regular intervals and the register storing temperature information can be updated at regular intervals. In another example, a thermal event (such as a temperature reaching or exceeding a threshold temperature) may trigger the register to be updated. Temperature data from the thermal sensors can be used in determining which RAS-based memory domain a memory resource is assigned to.

The memory device 1140 includes the controller 1150, which represents control logic within the memory device to control internal operations within the memory device. For example, the controller 1150 decodes commands sent by memory controller 1120 and generates internal operations to execute or satisfy the commands. The controller 1150 can be referred to as an internal controller, and is separate from memory controller 1120 of the host. The controller 1150 can determine what mode is selected based on the registers 1144, and configure the internal execution of operations for access to the memory resources 1160 or other operations based on the selected mode. The controller 1150 generates control signals to control the routing of bits within the memory device 1140 to provide a proper interface for the selected mode and direct a command to the proper memory locations or addresses. The controller 1150 includes command logic 1152, which can decode command encoding received on command and address signal lines. The command logic 1152 can be or include a command decoder. With the command logic 1152, memory device can identify commands and generate internal operations to execute requested commands.

Referring again to the host memory controller 1120, the memory controller 1120 includes address decoding logic 1123 to decode physical address information received from the processor 1110 into device addresses for memory devices 1140. The memory controller 1120 includes command (CMD) logic 1124, which represents logic or circuitry to generate commands to send to the memory devices 1140. The generation of the commands can refer to the command prior to scheduling, or the preparation of queued commands ready to be sent. Generally, the signaling in memory subsystems includes address information within or accompanying the command to indicate or select one or more memory locations where the memory devices should execute the command. In response to scheduling of transactions for the memory device 1140, the memory controller 1120 can issue commands via the I/O 1122 to cause the memory device 1140 to execute the commands. In one example, the controller 1150 of memory device 1140 receives and decodes command and address information received via I/O 1142 from the memory controller 1120. Based on the received command and address information, the controller 1150 can control the timing of operations of the logic and circuitry within the memory device 1140 to execute the commands. The controller 1150 is responsible for compliance with standards or specifications within the memory device 1140, such as timing and signaling requirements. The memory controller 1120 can implement compliance with standards or specifications by access scheduling and control.

The memory controller 1120 includes scheduler 1130, which represents logic or circuitry to generate and order transactions to send to memory device 1140. From one perspective, the primary function of the memory controller 1120 could be said to schedule memory access and other transactions to the memory device 1140. Such scheduling can include generating the transactions themselves to implement the requests for data by the processor 1110 and to maintain integrity of the data (e.g., such as with commands related to refresh). The transactions can include one or more commands, and result in the transfer of commands or data or both over one or multiple timing cycles such as clock cycles or unit intervals. Transactions can be for access such as read or write or related commands or a combination, and other transactions can include memory management commands for configuration, settings, data integrity, or other commands or a combination.

In the illustrated example, the memory controller 1120 includes RAS-based memory domain logic 1137. The RAS-based memory domain logic 1137 includes hardware logic for implementing one or more aspects of a RAS-based memory domain infrastructure, such as one or more of the interfaces 409, prediction logic 410, error monitoring logic 412, data migration logic 414, RAS features management logic 416, and NUMA RAS logic 418 of FIG. 4.

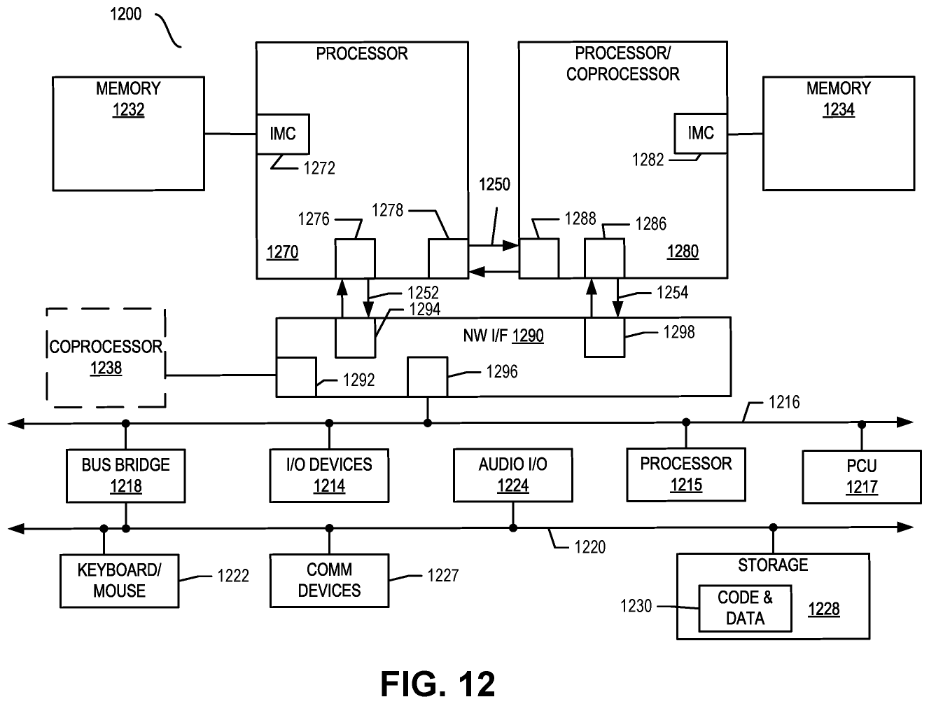

FIG. 12 illustrates an example computing system in which RAS-based memory domains can be implemented. Multiprocessor system 1200 is an interfaced system and includes a plurality of processors or cores including a first processor 1270 and a second processor 1280 coupled via an interface 1250 such as a point-to-point (P-P) interconnect, a fabric, and/or bus. In some examples, the first processor 1270 and the second processor 1280 are homogeneous. In some examples, first processor 1270 and the second processor 1280 are heterogenous. Though the example system 1200 is shown to have two processors, the system may have three or more processors, or may be a single processor system. In some examples, the computing system is a system on a chip (SoC).

Processors 1270 and 1280 are shown including integrated memory controller (IMC) circuitry 1272 and 1282, respectively. Processor 1270 also includes interface circuits 1276 and 1278; similarly, second processor 1280 includes interface circuits 1286 and 1288. Processors 1270, 1280 may exchange information via the interface 1250 using interface circuits 1278, 1288. IMCs 1272 and 1282 couple the processors 1270, 1280 to respective memories, namely a memory 1232 and a memory 1234, which may be portions of main memory locally attached to the respective processors.

Processors 1270, 1280 may each exchange information with a network interface (NW I/F) 1290 via individual interfaces 1252, 1254 using interface circuits 1276, 1294, 1286, 1298. The network interface 1290 (e.g., one or more of an interconnect, bus, and/or fabric, and in some examples is a chipset) may optionally exchange information with a coprocessor 1238 via an interface circuit 1292. In some examples, the coprocessor 1238 is a special-purpose processor, such as, for example, a high-throughput processor, a network or communication processor, compression engine, graphics processor, general purpose graphics processing unit (GPGPU), neural-network processing unit (NPU), embedded processor, or the like.

A shared cache (not shown) may be included in either processor 1270, 1280 or outside of both processors, yet connected with the processors via an interface such as P-P interconnect, such that either or both processors' local cache information may be stored in the shared cache if a processor is placed into a low power mode.

Network interface 1290 may be coupled to a first interface 1216 via interface circuit 1296. In some examples, first interface 1216 may be an interface such as a Peripheral Component Interconnect (PCI) interconnect, a PCI Express interconnect or another I/O interconnect. In some examples, first interface 1216 is coupled to a power control unit (PCU) 1217, which may include circuitry, software, and/or firmware to perform power management operations with regard to the processors 1270, 1280 and/or coprocessor 1238. PCU 1217 provides control information to a voltage regulator (not shown) to cause the voltage regulator to generate the appropriate regulated voltage. PCU 1217 also provides control information to control the operating voltage generated. In various examples, PCU 1217 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

PCU 1217 is illustrated as being present as logic separate from the processor 1270 and/or processor 1280. In other cases, PCU 1217 may execute on a given one or more of cores (not shown) of processor 1270 or 1280. In some cases, PCU 1217 may be implemented as a microcontroller (dedicated or general-purpose) or other control logic configured to execute its own dedicated power management code, sometimes referred to as P-code. In yet other examples, power management operations to be performed by PCU 1217 may be implemented externally to a processor, such as by way of a separate power management integrated circuit (PMIC) or another component external to the processor. In yet other examples, power management operations to be performed by PCU 1217 may be implemented within BIOS or other system software.

Various I/O devices 1214 may be coupled to first interface 1216, along with a bus bridge 1218 which couples first interface 1216 to a second interface 1220. In some examples, one or more additional processor(s) 1215, such as coprocessors, high throughput many integrated core (MIC) processors, GPGPUs, accelerators (such as graphics accelerators or digital signal processing (DSP) units), field programmable gate arrays (FPGAs), or any other processor, are coupled to first interface 1216. In some examples, second interface 1220 may be a low pin count (LPC) interface. Various devices may be coupled to second interface 1220 including, for example, a keyboard and/or mouse 1222, communication devices 1227 and storage circuitry 1228. Storage circuitry 1228 may be one or more non-transitory machine-readable storage media as described below, such as a disk drive or other mass storage device which may include instructions/code and data 1230. Further, an audio I/O 1224 may be coupled to second interface 1220. Note that other architectures than the point-to-point architecture described above are possible. For example, instead of the point-to-point architecture, a system such as multiprocessor system 1200 may implement a multi-drop interface or other such architecture.

As discussed above, in some embodiment the processors illustrated herein may comprise Other Processing Units (collectively termed XPUs). Examples of XPUs include one or more of Graphic Processor Units (GPUs) or General Purpose GPUs (GP-GPUs), Tensor Processing Units (TPUs), Data Processing Units (DPUs), Infrastructure Processing Units (IPUs), Artificial Intelligence (AI) processors or AI inference units and/or other accelerators, FPGAs and/or other programmable logic (used for compute purposes), etc. While some of the diagrams herein show the use of CPUs, this is merely exemplary and non-limiting. Generally, any type of XPU may be used in place of a CPU in the illustrated embodiments. Moreover, as used in the following claims, the term “processor” is used to generically cover CPUs and various forms of XPUs.

While various embodiments described herein use the term System-on-a-Chip or System-on-Chip (“SoC”) to describe a device or system having a processor and associated circuitry (e.g., Input/Output (“I/O”) circuitry, power delivery circuitry, memory circuitry, etc.) integrated monolithically into a single Integrated Circuit (“IC”) die, or chip, the present disclosure is not limited in that respect. For example, in various embodiments of the present disclosure, a device or system can have one or more processors (e.g., one or more processor cores) and associated circuitry (e.g., Input/Output (“I/O”) circuitry, power delivery circuitry, etc.) arranged in a disaggregated collection of discrete dies, tiles and/or chiplets (e.g., one or more discrete processor core die arranged adjacent to one or more other die such as memory die, I/O die, etc.). In such disaggregated devices and systems the various dies, tiles and/or chiplets can be physically and electrically coupled together by a package structure including, for example, various packaging substrates, interposers, active interposers, photonic interposers, interconnect bridges and the like. The disaggregated collection of discrete dies, tiles, and/or chiplets can also be part of a System-on-Package (“SoP”).

Examples of RAS-based memory domains follow.

Example 1: a method including: receiving information to indicate reliability of a memory resource, determining, based on the information to indicate the reliability of the memory resource, a likelihood of errors in the memory resource, and classifying the memory resource into one of multiple reliability, availability, and serviceability (RAS)-based memory domains based on the likelihood of errors in the memory resource.

Example 2: The method of example 1, wherein: the memory resource includes one or more of: a memory pool, a memory module, device-attached memory, and a dual inline memory module (DIMM).

Example 3: The method of examples 1 or 2, wherein: the multiple RAS-based memory domains include at least two domains of memory resources, including a lower RAS memory domain and a higher RAS memory domain.

Example 4: The method of any of examples 1-3, wherein: the information to indicate the reliability of the memory resource includes one or more of: information related to errors encountered in the memory resource, RAS capabilities for the memory resource, and temperature data.

Example 5: The method of any of examples 1-4, wherein: the information to indicate the reliability of the memory resource is received in response to the memory resource being added as an available memory resource.

Example 6: The method of any of examples 1-5, wherein: the information to indicate the reliability of the memory resource is received in response to an error encountered in the memory resource or in response to an error threshold being exceeded.

Example 7: The method of any of examples 1-6, further including: receiving, from an application, a request to allocate memory, the request including a value to indicate a requested level of memory reliability, and in response to the request, allocating memory in a RAS-based memory domain based on the requested level of memory reliability.

Example 8: The method in example 7, wherein: allocating the memory in the RAS-based memory domain includes: allocating memory mapped to one or more physical addresses assigned to the RAS-based memory domain.

Example 9: The method of any of examples 1-8, further including: reclassifying at least one page in the memory resource into a second RAS-based memory domain based on a change in the likelihood of errors in the page and remapping a physical address range based on the reclassification.

Example 10: The method of example 9, further including: copying data from the reclassified page in the memory resource to a different page in a desired RAS-based memory domain in response to the reclassification.

Example 11: The method of any of examples 1-10, further including: updating RAS-based memory domain information in a page table for physical addresses moved to a different RAS-based memory domain.

Example 12: The method of any of examples 1-11, wherein: a RAS-based memory domain includes at least a portion of multiple memory resources.

Example 13: A method including: classifying memory resources into RAS-based memory domains based on an expected likelihood of errors in the memory resources, receiving, from an application, a request to allocate memory, the request including a value to indicate a requested level of memory reliability, and in response to the request, allocating memory in one of multiple RAS-based memory domains based on the requested level of memory reliability.

Example 14: The method of example 13, further including: receiving information to indicate reliability of a memory resource, and determining, based on the information to indicate the reliability of the memory resource, the likelihood of errors in the memory resource.

Example 15: A non-transitory machine-readable medium having instructions stored thereon configured to be executed on one or more processors to perform a method in accordance with any of examples 1-14.

Example 16: A controller including: input/output (I/O) interface circuitry to couple with one or more memory resources, and logic to: reconfigure a mapping of physical addresses to locations in the one or more memory resources in response to reclassification of at least one location in the one or more memory resources from a first RAS-based memory domain to a second RAS-based memory domain.

Example 17: The controller of example 16, wherein: the logic is to reconfigure the mapping in response to a request from an operating system.

Example 18: The controller of any of examples 16-17, wherein: the logic is to: monitor errors in the one or more memory resources, and reconfigure the mapping in response to a number, percentage, or rate of errors exceeding a threshold.

Example 19: The controller of any of examples 16-18, wherein: the logic is to: copy data from the at least one reclassified location to a different location in the first RAS-based memory domain.

Example 20: The controller of example 19, wherein: the logic to reconfigure the mapping is to: remap a physical address or address range previously mapped to the at least one reclassified location to the different location.

Example 21: The controller of example 19, wherein: remapping a second physical address or address range to the at least one reclassified location.

Flow diagrams as illustrated herein provide examples of sequences of various process actions. The flow diagrams can indicate operations to be executed by a software or firmware routine, as well as physical operations. In one embodiment, a flow diagram can illustrate the state of a finite state machine (FSM), which can be implemented in hardware and/or software. Although shown in a particular sequence or order, unless otherwise specified, the order of the actions can be modified. Thus, the illustrated embodiments should be understood only as an example, and the process can be performed in a different order, and some actions can be performed in parallel. Additionally, one or more actions can be omitted in various embodiments; thus, not all actions are required in every embodiment. Other process flows are possible.

Note that actions triggered in response to a value being greater than or lower than a threshold can mean greater than or equal to, or lower than or equal to, and are design choices. Thus, it is understood that the terms “greater than” or “lower than” a threshold are intended to encompass embodiments in which a trigger occurs in response to the value being “greater than or equal to” or “lower than or equal to.”

To the extent various operations or functions are described herein, they can be described or defined as software code, instructions, configuration, and/or data. The content can be directly executable (“object” or “executable” form), source code, or difference code (“delta” or “patch” code). The software content of the embodiments described herein can be provided via an article of manufacture with the content stored thereon, or via a method of operating a communication interface to send data via the communication interface. A machine readable storage medium can cause a machine to perform the functions or operations described and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

The hardware design embodiments discussed above may be embodied within a semiconductor chip and/or as a description of a circuit design for eventual targeting toward a semiconductor manufacturing process. In the case of the later, such circuit descriptions may take of the form of a (e.g., VHDL or Verilog) register transfer level (RTL) circuit description, a gate level circuit description, a transistor level circuit description or mask description or various combinations thereof. Circuit descriptions are typically embodied on a computer readable storage medium (such as a CD-ROM or other type of storage technology).

Besides what is described herein, various modifications can be made to the disclosed embodiments and implementations of the invention without departing from their scope. Therefore, the illustrations and examples herein should be construed in an illustrative, and not a restrictive sense. The scope of the invention should be measured solely by reference to the claims that follow.

What is claimed is:

1. A non-transitory machine-readable medium having instructions stored thereon configured to be executed on one or more processors to perform a method, the method comprising:
receiving information to indicate reliability of a memory resource;
determining, based on the information to indicate the reliability of the memory resource, a likelihood of errors in the memory resource; and
classifying the memory resource into one of multiple reliability, availability, and serviceability (RAS)-based memory domains based on the likelihood of errors in the memory resource.

2. The non-transitory machine-readable medium of claim 1, wherein:
the memory resource includes one or more of: a memory pool, a memory module, device-attached memory, and a dual inline memory module (DIMM).

3. The non-transitory machine-readable medium of claim 1, wherein:
the multiple RAS-based memory domains include at least two domains of memory resources, including a lower RAS memory domain and a higher RAS memory domain.

4. The non-transitory machine-readable medium of claim 1, wherein:
the information to indicate the reliability of the memory resource includes one or more of: information related to errors encountered in the memory resource, RAS capabilities for the memory resource, and temperature data.

5. The non-transitory machine-readable medium of claim 1, wherein:
the information to indicate the reliability of the memory resource is received in response to the memory resource being added as an available memory resource.

6. The non-transitory machine-readable medium of claim 1, wherein:
the information to indicate the reliability of the memory resource is received in response to an error encountered in the memory resource or in response to an error threshold being exceeded.

7. The non-transitory machine-readable medium of claim 1, the method further comprising:
receiving, from an application, a request to allocate memory, the request including a value to indicate a requested level of memory reliability; and
in response to the request, allocating memory in a RAS-based memory domain based on the requested level of memory reliability.

8. The non-transitory machine-readable medium of claim 7, wherein:
allocating the memory in the RAS-based memory domain includes: allocating memory mapped to one or more physical addresses assigned to the RAS-based memory domain.

9. The non-transitory machine-readable medium of claim 1, the method further comprising:
reclassifying at least one page in the memory resource into a second RAS-based memory domain based on a change in the likelihood of errors in the page; and
remapping a physical address range based on the reclassification.

10. The non-transitory machine-readable medium of claim 9, the method further comprising:
copying data from the reclassified page in the memory resource to a different page in a desired RAS-based memory domain in response to the reclassification.

11. The non-transitory machine-readable medium of claim 9, the method further comprising:
updating RAS-based memory domain information in a page table for physical addresses moved to a different RAS-based memory domain.

12. The non-transitory machine-readable medium of claim 1, wherein:
a RAS-based memory domain includes at least a portion of multiple memory resources.

13. A non-transitory machine-readable medium having instructions stored thereon configured to be executed on one or more processors to perform a method, comprising:
classifying memory resources into RAS-based memory domains based on an expected likelihood of errors in the memory resources;
receiving, from an application, a request to allocate memory, the request including a value to indicate a requested level of memory reliability; and
in response to the request, allocating memory in one of multiple RAS-based memory domains based on the requested level of memory reliability.

14. The non-transitory machine-readable medium of claim 13, the method further comprising:
receiving information to indicate reliability of a memory resource; and
determining, based on the information to indicate the reliability of the memory resource, the likelihood of errors in the memory resource.

15. A controller comprising:
input/output (I/O) interface circuitry to couple with one or more memory resources; and
logic to:
reconfigure a mapping of physical addresses to locations in the one or more memory resources in response to reclassification of at least one location in the one or more memory resources from a first RAS-based memory domain to a second RAS-based memory domain.

16. The controller of claim 15, wherein:
the logic is to reconfigure the mapping in response to a request from an operating system.

17. The controller of claim 15, wherein:
the logic is to:
monitor errors in the one or more memory resources, and
reconfigure the mapping in response to a number, percentage, or rate of errors exceeding a threshold.

18. The controller of claim 15, wherein:
the logic is to:
copy data from the at least one reclassified location to a different location in the first RAS-based memory domain.

19. The controller of claim 18, wherein:
the logic to reconfigure the mapping is to:
remap a physical address or address range previously mapped to the at least one reclassified location to the different location.

20. The controller of claim 19, wherein:
remapping a second physical address or address range to the at least one reclassified location.
